(19) United States
(12) Patent Application Publication
(10) Pub. No.: US 2026/0221192 A1
(43) Pub. Date: Jul. 30, 2026

(54) OPERATING METHOD OF STORAGE DEVICE

(71) Applicant: SK hynix Inc., Gyeonggi-do (KR)

(72) Inventor: Sagar Rajendrabhai Upadhyay, San Jose, CA (US)

(21) Appl. No.: 19/037,415

(22) Filed: Jan. 27, 2025

(51) Int. Cl. G11C 16/10; G11C 16/16; G11C 16/34

(52) U.S. Cl. CPC G11C 16/102; G11C 16/16; G11C 16/3459

(57) ABSTRACT

An operating method of a storage device includes performing a partial-foggy program operation of programming, into a physical page including target memory cells, lower logical page data units externally provided; and performing a fine program operation of programming, into the physical page, a combination of higher logical page data units externally provided and the lower logical page data units read from the physical page. Performing the partial-foggy program operation includes performing a pre-erase-tightening operation on the target memory cells within the physical page while a last lower logical page data unit is being externally provided; and performing subsequent program loops on the physical page with the lower logical page data units which are completely provided to the storage device.

### BACKGROUND

### 1. Field

Embodiments of the present disclosure relate to a storage device and an operating method thereof.

### 2. Description of the Related Art

A storage system stores data in response to a request from a host system such as a computer, smartphone, or smart pad. An example of a storage system is a system configured to store data in a semiconductor memory, especially in a nonvolatile memory, such as a solid-state drive (SSD) or a memory card.

A storage system includes a storage device configured to store data and a controller configured to control the storage device. Generally, a storage device can be volatile or non-volatile. Examples of a non-volatile storage device are Read Only Memory (ROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), and Ferroelectric RAM (FRAM).

### SUMMARY

In an embodiment of the present disclosure, an operating method of a storage device may include performing a partial-foggy program operation of programming, into a physical page including target memory cells, lower logical page data units externally provided; and performing a fine program operation of programming, into the physical page, a combination of higher logical page data units externally provided and the lower logical page data units read from the physical page. Performing the partial-foggy program operation includes performing a pre-erase-tightening operation on the target memory cells within the physical page while a last one of the lower logical page data units is being externally provided; and performing subsequent program loops on the physical page with the lower logical page data units which are completely provided to the storage device.

Each of the target memory cells may be a quadruple-level cell (QLC). The lower logical page data units may be least significant bit (LSB) page data and lower-central significant bit (LCSB) page data. The higher logical page data units may be upper-central significant bit (UCSB) page data and most significant bit (MSB) page data.

The partial-foggy program operation may be performed for each of the target memory cells to belong to one of erase state and first to third program states.

The last one of the lower logical page data units may be the LCSB data.

The subsequent program loops may be performed according to an incremental step pulse program (ISPP) scheme.

Performing the pre-erase-tightening operation may include performing a pre-erase verification process of verifying the target memory cells with a pre-erase-pass threshold voltage to program-inhibit a pre-erase-pass memory cell having a higher threshold voltage than the pre-erase-pass threshold voltage among the target memory cells; and performing a pre-program loop including a program pulse application process and a verification process on remaining target memory cells other than the pre-erase-pass memory cell among the target memory cells. The program pulse application process may include applying a program pulse to the remaining target memory cells. The verification process includes verifying the remaining target memory cells with the pre-erase-pass threshold voltage to program-inhibit a target memory cell which becomes to have a higher threshold voltage than the pre-erase-pass threshold voltage among the remaining target memory cells.

The pre-erase-pass threshold voltage may be higher than a pass threshold voltage corresponding to an erase state.

Performing the pre-erase-tightening operation may further include performing, after completion of the program pulse application process, a cell-status-change operation of changing the target memory cells which are to have threshold voltages corresponding to the respective program states other than an erase state and have been program-inhibited by the pre-erase-tightening operation, to become program-permitted.

The cell-status-change operation may be performed based on the lower logical page data units which are completely provided to the storage device.

Performing the pre-erase-tightening operation may further include suspending the partial-foggy program operation when the lower logical data units are not yet completely provided to the storage device during the cell-status-change operation.

Performing the pre-erase-tightening operation may further include resuming the suspended partial-foggy program operation when the lower logical data units are completely provided to the storage device.

Performing the fine program operation may include performing an internal pre-read operation of internally reading the lower logical page data units from the physical page while a last higher logical page data unit is being externally provided; combining the externally provided higher logical page data units which are completely provided to the storage device, and the lower logical page data units read from the physical page; and performing subsequent program loops on the physical page with the combined data units.

Each of the target memory cells may be a quadruple-level cell (QLC). The lower logical page data units may be least significant bit (LSB) page data and lower-central significant bit (LCSB) page data. The higher logical page data units may be upper-central significant bit (UCSB) page data and most significant bit (MSB) page data. The last lower logical page data unit is the MSB data.

The fine program operation may be performed for each of the target memory cells to belong to one of erase state and first to fifteenth program states.

Performing the fine program operation may further include suspending the fine program operation when the higher logical data units are not yet completely provided to the storage device during the internal pre-read operation.

Performing the fine program operation may be performed to further include resuming the suspended fine program operation when the higher logical data units are completely provided to the storage device.

Additional embodiments of the present disclosure will become apparent from the following description.

### BRIEF DESCRIPTION OF THE DRAWINGS

FIG. 1 is a block diagram illustrating a storage system.

FIG. 2 is a diagram illustrating a configuration of storage device.

FIG. 3 is a diagram illustrating a memory cell array.

FIG. 4 is a diagram schematically illustrating a program operation according to a program loop scheme.

FIG. 5 is a diagram schematically illustrating program loops each including program pulse application process and verification processes.

FIGS. 6 and 7 illustrate the partial-foggy-fine program operation on TLCs.

FIGS. 8 to 10 illustrate read operations on LSB, CSB and MSB pages of TLCs.

FIG. 11 schematically illustrates pages included in a memory block.

FIG. 12 is a timing diagram illustrating a partial-foggy-fine program operation.

FIG. 13 illustrates a threshold voltage distribution as a result of a pre-erase-tightening operation within a partial-foggy program operation.

FIG. 14 is a timing diagram illustrating the partial-foggy program operations according to the prior art and an embodiment of the present disclosure.

FIG. 15 schematically illustrates target memory cells as a result of pre-erase verification process according to an embodiment of the present disclosure.

FIG. 16 illustrates the relationship among a pre-erase verification process, a program pulse application process and a cell-status-change operation within a pre-erase-tightening operation according to an embodiment of the present disclosure.

FIG. 17 is a timing diagram illustrating the fine program operations according to the prior art and an embodiment of the present disclosure.

### DETAILED DESCRIPTION

Various embodiments of the present disclosure are described below in more detail with reference to the accompanying drawings. The present invention may, however, be embodied in different forms and thus should not be construed as limited to the embodiments set forth herein. Rather, these embodiments are provided so that this disclosure conveys the scope of the present invention to those skilled in the art. Moreover, reference herein to “an embodiment,” “another embodiment,” or the like is not necessarily to only one embodiment, and different references to any such phrase are not necessarily to the same embodiment(s). The term “embodiments” as used herein does not necessarily refer to all embodiments. Throughout this disclosure, like reference numerals refer to like parts in the figures and embodiments of the present disclosure.

Embodiments of the present disclosure can be implemented in numerous ways, including as a process; an apparatus; a system; a computer program product embodied on a computer-readable storage medium; and/or a processor, such as a processor suitable for executing instructions stored on and/or provided by a memory coupled to the processor. In general, the order of the operations of disclosed processes may be altered within the scope of the embodiments. Unless stated otherwise, a component such as a processor or a memory described as being suitable for performing a task may be implemented as a general device or circuit component that is configured or otherwise programmed to perform the task at a given time or as a specific device or circuit component that is manufactured to perform the task. As used herein, the term ‘processor’ or the like refers to one or more devices, circuits, and/or processing cores suitable for processing data, such as computer program instructions.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described herein, the code or instructions for implementing the operations of the method embodiments may transform the computer, processor, controller, or other signal processing device into a special-purpose processor for performing methods herein.

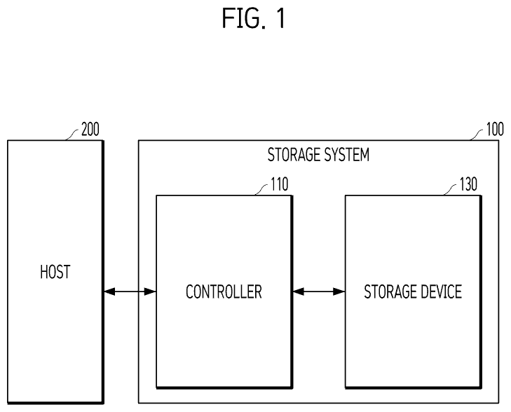

FIG. 1 is a block diagram illustrating a storage system 100.

Referring to FIG. 1, the storage system 100 may include a storage device 130 and a controller 110.

The storage system 100 may access data stored therein in response to a request from a host system 200. Examples of the host system 200 include a cellular phone, a smartphone, an MP3 player, a laptop computer, a desktop computer, a game player, a TV, a tablet PC, and an in-vehicle infotainment system.

The storage system 100 may be implemented as any of various types of storage systems. For example, the storage system 100 may be implemented as a solid state drive (SSD), a multimedia card in the form of a multimedia card (MMC), (e.g., an eMMC, an RS-MMC, or a micro-MMC), a secure digital card in the form of an SD (e.g., a mini-SD or a micro-SD), a universal serial bus (USB) storage device, a universal flash storage (UFS) device, a personal computer memory card international association (PCMCIA) card type storage device, a peripheral component interconnection (PCI) card type storage device, a PCI express (PCI-e) card type storage device, a compact flash (CF) card, a smart media card, or a memory stick.

The storage system 100 may be manufactured through any of various types of packages. For example, the storage system 100 may be manufactured through a package on package (POP), a system in package (SIP), a system on chip (SOC), a multi-chip package (MCP), a chip on board (COB), a wafer-level fabricated package (WFP), or a wafer-level stack package (WSP).

The storage device 130 may access data stored therein. The storage device 130 may operate in response to a command from the controller 110. The storage device 130 may include a memory cell array 210 including a plurality of memory cells configured to store data therein. The memory cell array may include a plurality of memory blocks. Each of the memory blocks may include pages, each of which includes memory cells. According to an embodiment, data may be stored in and readout from the storage device 130 in units of pages. Data may be erased or removed from the storage device 130 in units of blocks.

According to an embodiment, the storage device 130 may be any of Double Data Rate Synchronous Dynamic Random-Access Memory (DDR SDRAM), Low Power Double Data Rate4 (LPDDR4) SDRAM, Graphics Double Data Rate (GDDR) SDRAM, Low Power DDR (LPDDR), Rambus Dynamic Random Access Memory (RDRAM), NAND flash memory, Vertical NAND flash memory, NOR flash memory, resistive random-access memory (RRAM), phase-change random-access memory (PRAM), magneto-resistive random-access memory (MRAM), ferroelectric random-access memory (FRAM), spin-transfer torque random-access memory (STT-RAM) and so forth. By way of example, the storage device 130 can be a NAND flash memory in the context of the following description.

The storage device 130 may have a two-dimensional or three-dimensional array structure. The embodiments of the present disclosure may be applied not only to a flash memory device, in which a charge storage layer includes a conductive floating gate (FG), but also to a charge trap flash (CTF) memory device, in which a charge storage layer includes an insulating layer.

The storage device 130 may receive a command and an address from the controller 110. The storage device 130 may access, in response to the command, an area selected by the address within the memory cell array. For example, the storage device 130 may perform, in response to the command, various operations such as a write operation or a program operation, a read operation and an erase operation. For example, during the program operation, the storage device 130 may program data into the selected area. During the read operation, the storage device 130 may read data from the selected area. During the erase operation, the storage device 130 may erase or remove data from the selected area.

The controller 110 may control the operation of the memory device 50.

When a power voltage is applied to the storage system 100, the controller 110 may execute firmware such as a Flash Translation Layer (FTL) for controlling communication between the host system 200 and the storage device 130.

According to an embodiment, the controller 110 may receive data and a logical address from the host system 200 and include firmware that translates the logical address into a physical address. A logical address may be identified by the host system 200 and may indicate a logical location within the storage device 130. A physical address may indicate an actual location within the storage device 130. The controller 110 may manage, in an operational memory, a logical-to-physical map table representing a mapping relationship between the logical address and the physical address.

In response to a request from the host system 200, the controller 110 may control the storage device 130 to perform an operation. For example, in response to a program request from the host system 200, the controller 110 may provide a program command, a physical address and data to the storage device 130. In response to a read request provided together with a logical address from the host system 200, the controller 110 may provide the storage device 130 with the read command and a physical address corresponding to the logical address. In response to an erase request provided together with a logical address from the host system 200, the controller 110 may provide the storage device 130 with an erase command and a physical address corresponding to the logical address.

Without a request from the host system 200, the controller 110 may control the storage device 130 to perform a background operation such as a program operation for wear leveling or for garbage collection.

According to an embodiment, the storage system 100 may further include an operational memory. The controller 110 may control data exchange between the host system 200 and the operational memory. The controller 110 may temporarily store, in the operational memory, system data for controlling the storage device 130. For example, the controller 110 may temporarily store, in the operational memory, data from the host system 200 and transfer the temporarily stored data to the storage device 130.

As a buffer memory, the operational memory may store codes or commands executed by the controller 110. As a cache memory, the operational memory may store data processed by the controller 110.

According to an embodiment, the operational memory may be any of DRAM such as DDR SDRAM, LPDDR4 SDRAM, GDDR SDRAM, LPDDR or RDRAM, SRAM and so forth.

The host system 200 may communicate with the storage system 100 through at least one of various communication interfaces or standards such as a Universal Serial Bus (USB), Serial AT Attachment (SATA), a Serial Attached SCSI (SAS), a High Speed Interchip (HSIC), a Small Computer System Interface (SCSI), a Peripheral Component Interconnection (PCI), PCI express (PCIe), NonVolatile Memory express (NVMe), Universal Flash Storage (UFS), Secure Digital (SD), a Multi-Media Card (MMC), an embedded MMC (eMMC), a Dual In-line Memory Module (DIMM), a Registered DIMM (RDIMM), a Load Reduced DIMM (LRDIMM) and so forth.

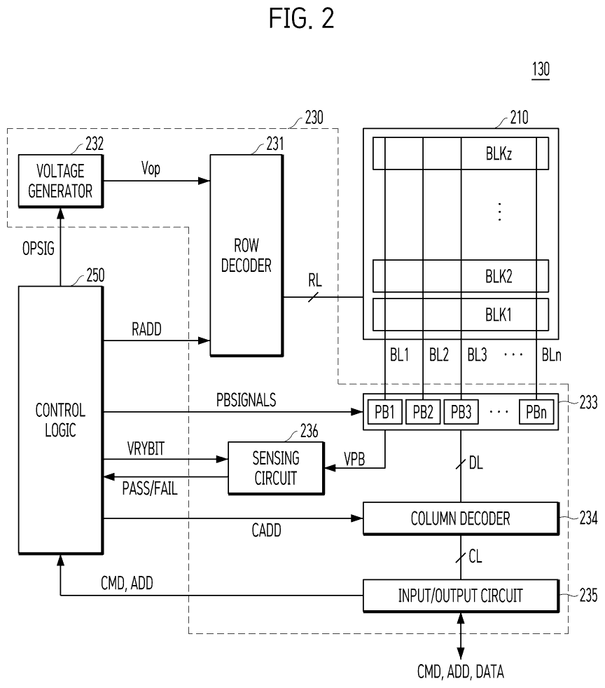

FIG. 2 is a diagram illustrating a configuration of the storage device 130.

Referring to FIG. 2, the storage device 130 may include the memory cell array 210, an operating circuit 230 and a control logic 250. The operating circuit 230 and control logic 250 may be collectively referred to as a control circuit.

The memory cell array 210 may include a plurality of memory blocks BLK1 to BLKz coupled to a row decoder 231 through row lines RL, each configured by at least one source select line, a plurality of word lines, and at least one drain select line. The plurality of memory blocks BLK1 to BLKz may be coupled to a page buffer group 233 through bit lines BL1 to BLn. Each of the plurality of memory blocks BLK1 to BLKz may include a plurality of pages. A page may be defined as a group of memory cells coupled to a single word line. The plurality of memory cells may be nonvolatile.

According to an embodiment, the memory cell array 210 may include any of a single-level cell (SLC), a multi-level cell (MLC), a triple-level cell (TLC), a quadruple-level cell (QLC), and a further-higher-level cell, which will not limit the scope of the present disclosure.

The operating circuit 230 may be operable under the control of the control logic 250. The operating circuit 230 may perform an operation on a selected area within the memory cell array 210. The operating circuit 230 may drive the memory cell array 210. For example, the operating circuit 230 may apply various operating voltages to the row lines RL and the bit lines BL1 to BLn or discharge the applied voltages.

The operating circuit 230 may include the row decoder 231, a voltage generator 232, the page buffer group 233, a column decoder 234, an input/output circuit 235 and a sensing circuit 236.

The row decoder 231 may be coupled to the memory cell array 210 through the row lines RL. Within the row lines RL, the word lines may include normal word lines and dummy word lines. The row lines RL may further include a pipe select line.

The row decoder 231 may decode a row address RADD from the control logic 250. The row decoder 231 may select, according to the decoded address, at least one of the memory blocks BLK1 to BLKz. The row decoder 231 may select, according to the decoded address, at least one of the word lines coupled to the selected memory block to apply a voltage Vop from the voltage generator 232 to the selected word line.

For example, during a program pulse application process, the row decoder 231 may apply a program voltage to the selected word line and a program pass voltage to unselected word lines. During a verification process, the row decoder 231 may apply a verification voltage to the selected word line and a verification pass voltage to the unselected word lines. During a read operation, the row decoder 231 may apply a read voltage to the selected word line and a read pass voltage to the unselected word lines. During an erase operation, the row decoder 231 may select, according to the decoded address, one of the memory blocks BLK1 to BLKz and may apply a ground voltage to word lines coupled to the selected memory block.

The voltage generator 232 may operate under the control of the control logic 250. The voltage generator 232 may generate various operating voltages Vop through an external power voltage supplied to the storage device 130 or an internal power voltage regulated from the external power voltage. The voltage generator 232 may generate, in response to an operation signal OPSIG, the operating voltages Vop for program, read and erase operations. For example, the voltage generator 232 may generate a program voltage, a verification voltage, a pass voltage, a read voltage, and an erase voltage.

The page buffer group 233 may include first to n-th page buffers PB1 to PBn coupled to the memory cell array 210 through the respective first to n-th bit lines BL1 to BLn. The first to n-th page buffers PB1 to PBn may operate under the control of the control logic 250. The first to n-th page buffers PB1 to PBn may operate in response to page buffer control signals PBSIGNALS. The first to n-th page buffers PB1 to PBn may temporarily store therein data provided through the first to n-th bit lines BL1 to BLn or may sense voltages or currents of the bit lines BL1 to BLn during a read or verification process.

When a program voltage is applied to a selected word line during a program pulse application process, the first to n-th page buffers PB1 to PBn may transfer data DATA from the column decoder 234 and the input/output circuit 235 to selected memory cells through the first to n-th bit lines BL1 to BLn. Memory cells of the selected page may be programmed according to the transferred data DATA. During a verification process, the first to n-th page buffers PB1 to PBn may sense a voltage or a current from the first to n-th bit lines BL1 to BLn to read page data from the selected memory cells.

Under the control of the column decoder 234 during a read operation, the first to n-th page buffers PB1 to PBn may read the data DATA from the memory cells of the selected page through the first to n-th bit lines BL1 to BLn and may output the read data DATA to the input/output circuit 235.

During an erase operation, the first to n-th page buffers PB1 to PBn may float the first to n-th bit lines BL1 to BLn or may apply an erase voltage to the first to n-th bit lines BL1 to BLn.

The column decoder 234 may transfer data between the input/output circuit 235 and the page buffer group 233 according to a column address CADD. For example, the column decoder 234 may exchange data with the first to n-th page buffers PB1 to PBn through data lines DL and with the input/output circuit 235 through column lines CL.

The input/output circuit 235 may transfer a command CMD and an address ADDR from the controller 110 to the control logic 250 and may exchange the data DATA with the column decoder 234.

During a read operation or a verification process, the sensing circuit 236 may generate a reference current according to an allowable bit VRYBIT. The sensing circuit 236 may compare a sensing voltage VPB from the page buffer group 233 with a reference voltage generated by the reference current. As a result of the comparison, the sensing circuit 236 may output a pass signal PASS or a fail signal FAIL.

In response to the command CMD and the address ADDR, the control logic 250 may control the operating circuit 230 through the operation signal OPSIG, the row address RADD, the page buffer control signals PBSIGNALS and the allowable bit VRYBIT. The control logic 250 may control a read operation on a selected memory block in response to a sub-block read command and an address. The control logic 250 may control an erase operation on a selected sub-block included in the selected memory block in response to a sub-block erase command and the address. The control logic 250 may determine whether a verification process passes or fails according to the pass or fail signal PASS or FAIL.

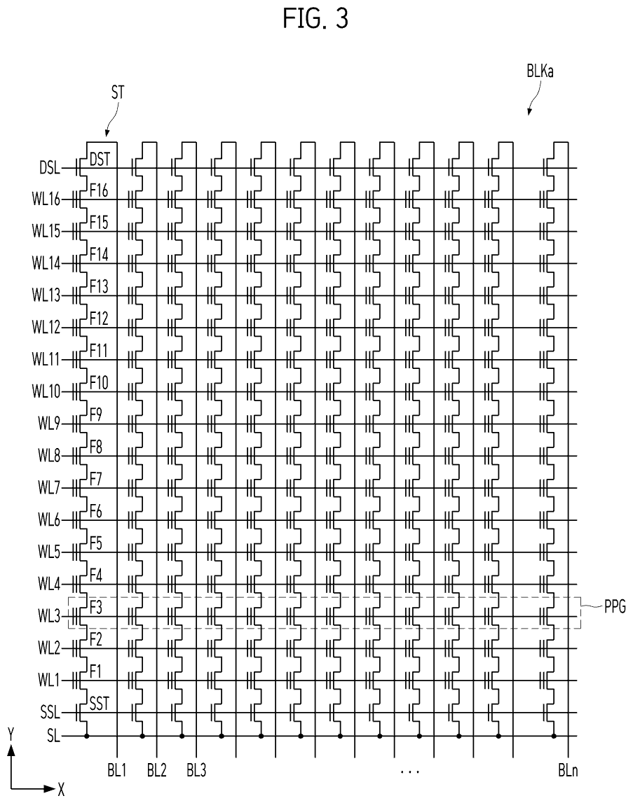

FIG. 3 is a diagram illustrating the memory cell array 210. FIG. 3 is a circuit diagram showing a representative memory block BLKa among the plurality of memory blocks BLK1 to BLKz in the memory cell array 210.

A first select line, word lines, and a second select line arranged in parallel with each other may be coupled to the memory block BLKa. The word lines may be arranged in parallel with each other between the first and second select lines. The first select line may be a source select line SSL and the second select line may be a drain select line DSL.

The memory block BLKa may include a plurality of strings coupled between the bit lines BL1 to BLn and a source line SL. The bit lines BL1 to BLn may be coupled to the respective strings and the strings may be commonly coupled to the source line SL. The strings may have the same configuration and a string ST coupled to the first bit line BL1 is described in detail as an example.

The string ST may include a source select transistor SST, a plurality of memory cells F1 to F16, and a drain select transistor DST coupled in series between the source line SL and the first bit line BL1. Although not illustrated, each string ST may include plural source select transistors SST, plural drain select transistors DST and more than the 16 memory cells F1 to F16.

A source of the source select transistor SST may be coupled to the source line SL and a drain of the drain select transistor DST may be coupled to the first bit line BL1. The memory cells F1 to F16 may be coupled in series between the source select transistor SST and the drain select transistor DST. Gates of the source select transistors SST included in different strings may be coupled to the source select line SSL. Gates of the drain select transistors DST included in the different strings may be coupled to the drain select line DSL. Gates of the memory cells F1 to F16 included in the different strings may be coupled to respective word lines WL1 to WL16. A group of memory cells coupled to the same word line among memory cells included in different strings may be referred to as a physical page PPG. The memory block BLKa may include as many physical pages PPG as the number of word lines WL1 to WL16.

The single physical page PPG including SLCs may store data of a single logical page LPG. The data of the single logical page LPG may include as many bits of data as the number of memory cells included in the single physical page PPG. The single physical page PPG including MLCs may store data of two or more logical pages LPG.

According to an embodiment, a memory block may have a three-dimensional structure. Each memory block may include a plurality of memory cells stacked over a substrate. The plurality of memory cells may be arranged in a +X direction, a +Y direction, and a +Z direction.

In an embodiment, the combination of the operating circuit 230 and the control logic 250 may be referred to as a control circuit. The control circuit may perform an operation on the memory cell array 210 as described herein. The control circuit may control the memory cell array 210 to perform an operation described herein.

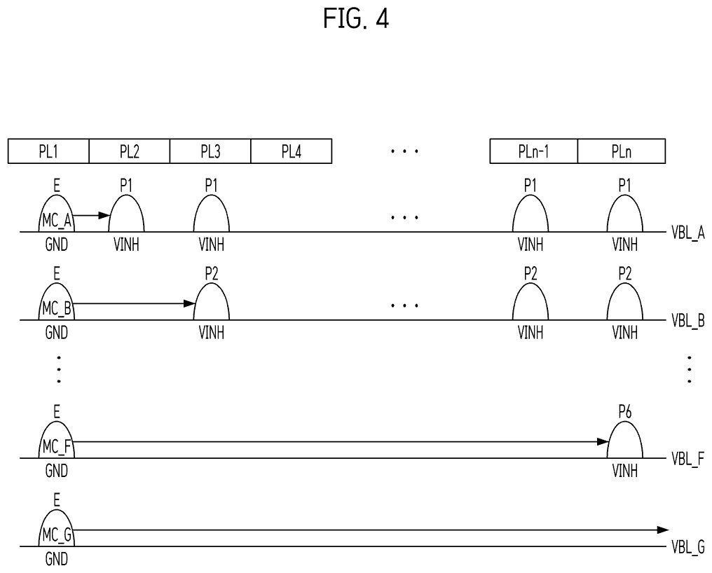

FIG. 4 is a diagram schematically illustrating a program operation according to a program loop scheme.

Referring to FIG. 4, the storage device 130 may perform a plurality of program loops PL1 to PLn, where n is any suitable natural number of 2 or greater, on selected memory cells during a program operation. A single program operation on a page may comprise the ‘n’ number of program loops PL1 to PLn at maximum. Each of the plurality of program loops PL1 to PLn may include a program pulse application process and a verification process. The storage device 130 may perform the verification process according to a corresponding verification voltage level.

In FIG. 4, by way of example, the memory cells are TLCs and programmed from the erase state E to one of first to seventh program states P1 to P7.

As an example, among the selected memory cells as target memory cells of the program operation, memory cells MC_A may be programmed to the first program state P1, memory cells MC_B to the second program state P2, memory cells MC_C to the third program state P3, memory cells MC_D to the fourth program state P4, memory cells MC_E to the fifth program state P5, memory cells MC_F to the sixth program state P6 and memory cells MC_G to the seventh program state P7. When the program operation is permitted to the memory cells MC_A to MC_F, a voltage of a bit line coupled to each of the memory cells MC_A to MC_F may be set to the ground voltage GND.

All memory cells MC_A may be programmed to the first program state P1 in the first program loop PL1. Accordingly, the program operation on the memory cells MC_A may be inhibited from the second program loop PL2. Accordingly, from the second program loop PL2, a voltage level of a bit line VBL_A coupled to each of the memory cells MC_A may be set to the program inhibition voltage level VINH.

All memory cells MC_B may be programmed to the second program state P2 in the second program loop PL2. Accordingly, the program operation on the memory cells MC_B may be inhibited from the third program loop PL3. Accordingly, from the third program loop PL3, a voltage level of a bit line VBL_B coupled to each of the memory cells MC_B may be set to the program inhibition voltage level VINH.

All memory cells MC_F may be programmed to the sixth program state P6 in the (n-1)th program loop PLn-1. Accordingly, the program operation on the memory cells MC_F may be inhibited from the n-th program loop PLn. Accordingly, from the n-th program loop PLn, a voltage level of a bit line VBL_F coupled to each of the memory cells MC_F may be set to the program inhibition voltage level VINH. When all memory cells MC_G are programmed to the seventh program state P7 in the n-th program loop PLn, all memory cells MC_A to MC_F may be regarded as properly programmed and thus the program operation may then end.

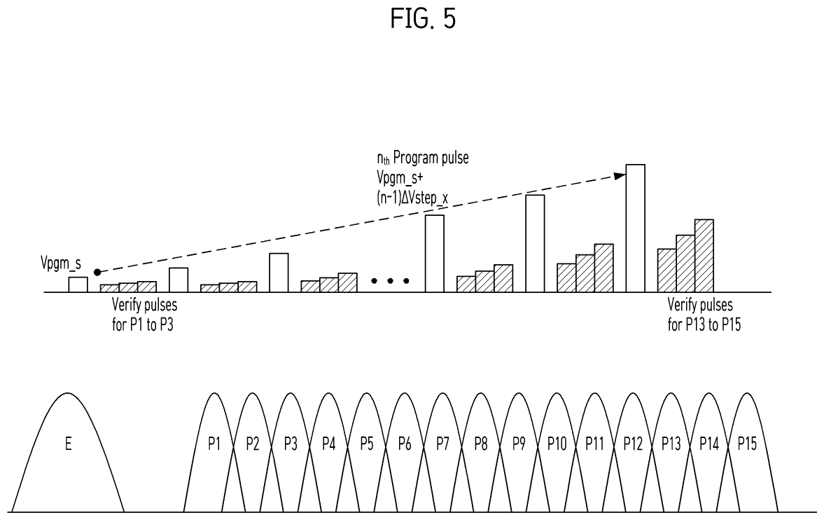

FIG. 5 is a diagram schematically illustrating the program loops each including the program pulse application process and verification processes.

Referring to FIG. 5, program data may be loaded into the first to n-th page buffers PB1 to PBn connected to the bit-lines of the memory cell array 210. The storage device 130 may perform a single program pulse application process to apply a single program pulse to all target memory cells except for erased memory cells. The verification processes may immediately follow the single program pulse application process to determine whether a threshold voltage of each memory cell becomes equal to or higher than a pass threshold voltage corresponding to a target program state. When the memory cell is determined to have the threshold voltage equal to or higher than the pass threshold voltage, the memory cell may become program-inhibited. By repeating the alternation of the program pulse application process and the verification processes, all target memory cells may become programmed to have threshold voltages corresponding to respective program states.

Referring to FIG. 5, according to the incremental step pulse program (ISPP) scheme, each time the program loop proceeds, the level of program pulse applied to the word line may increase by a step size Vstep_x from the level of the program pulse applied in a previous program loop. The step size may be predetermined. When all target memory cells connected to the selected word line do not reach the target program states even though the program loops are performed to a preset maximum number of times, it may be determined that the program operation has failed. The number of program states verified in each program loop may be at least two or more program states.

By a foggy program operation disclosed below, formed are threshold voltage distributions corresponding to a part of all states supposed to be formed. In this disclosure, a partial-foggy program operation may be the foggy program operation to form the threshold voltage distribution corresponding to a part of all program states supposed to be formed. In this disclosure, a partial-foggy-fine program operation may include the partial-foggy program operation and a fine program operation. The partial-foggy-fine program operation may improve an interference phenomenon affecting an adjacent cell due to a program operation in a three-dimensional memory cell array. As an example, a partial-foggy-fine program operation on TLCs is described below. However, the partial-foggy-fine program operation may be applied to memory cells of various multiple bits per cell (BPC) such as QLCs.

The partial-foggy-fine program operation may include step S100 of performing a partial-foggy program operation on selected memory cells using an intermediate verify voltage VRFIS and step S200 of performing a fine program operation on the selected memory cells using first to seventh verify voltages. The selected memory cells may belong to the physical page PPG subject to the partial-foggy-fine program operation. The selected memory cells may be coupled to a selected word line.

At step S100, threshold voltages of the selected memory cells may change from threshold voltages corresponding to an erase state E₀ to threshold voltages corresponding to an erase state E_{IS} and the intermediate program state P_{IS}. The partial-foggy program operation may temporarily change the threshold voltages of the selected memory cells to correspond to the erase state E_{IS} and the intermediate program state P_{IS} before changing, through the fine program operation, the threshold voltages of the selected memory cells to correspond to an erase state E and the target program states P1 to P7. The threshold voltages of the selected memory cells, which are supposed to belong to the intermediate program state P_{IS} by the partial-foggy program operation, may be verified through the intermediate verify voltage VRF_{IS}.

At step S200, the threshold voltages of the selected memory cells may change from threshold voltages corresponding to the erase state E_{IS} and the intermediate program state P_{IS} to threshold voltages corresponding to the erase state E and the target program states P1 to P7. Since the selected memory cells are TLCs as an example, the selected memory cells may belong to one of the eight states, i.e., the erase state E and the target program states P1 to P7, after completion of the partial-foggy-fine program operation. When each memory cell stores N bits, threshold voltages of the memory cells may belong to one of 2^{N} states, i.e., the erase state E and target program states P1 to P(2^{N}-1) after completion of a program operation.

For example, at step S200, the threshold voltages of the selected memory cells of the erase state E_{IS} may be changed to correspond to the erase state E and the first to third target program states P1 to P3. When each of the selected memory cells stores N bits, the threshold voltages of the selected memory cells of the erase state E_{IS} may be changed to correspond to the erase state E and the first to (2^{N-1}-1)th target program states P1 to P(2^{N-1}-1), for example.

In addition, at step S200, the threshold voltages of the selected memory cells of the intermediate program state P_{IS} may be changed to correspond to the fourth to seventh target program states P4 to P7. When each of the selected memory cell stores N bits, the threshold voltages of the selected memory cells of the intermediate program state P_{IS} may be changed to (2^{N-1})th to (2^{N}-1)th target program states P(2^{N-1}) to P(2^{N}-1), for example.

The threshold voltages of the selected memory cells, which are supposed to belong to the erase state E and the program states P1 to P7 by the fine program operation, may be verified through the first to seventh verify voltages. For example, when each of the selected memory cell stores N bits, first to (2^{N-1})th verify voltages may verify the threshold voltages of the selected memory cells.

Step S100 of performing the partial-foggy program operation on the selected memory cells using the intermediate verify voltage VRF_{IS} may include step S310 of applying a program inhibition voltage to bit lines coupled to the selected memory cells programmed to have the threshold voltages corresponding to the intermediate program state PIS and the erase state EIS; step S330 of applying a program permission voltage to bit lines coupled to the selected memory cells not yet programmed to have the threshold voltages corresponding to the intermediate program state PIS; step S350 of applying a program voltage to a word line coupled to the selected memory cells; step S370 of performing a verify operation on the selected memory cells using the intermediate verify voltage VRFIS; and step S390 of determining whether the selected memory cells are completely programmed to belong to the intermediate program state P_{IS}.

Each of the selected memory cells of the erase state E_{IS} may have a least significant bit (LSB) of the value ‘1’. The selected memory cells to be programmed to the intermediate program state P_{IS} may have a least significant bit (LSB) of the value ‘0’.

Steps S310 to S370 may be repeated until the selected memory cells are programmed to have the threshold voltages corresponding to the intermediate program state P_{IS}. The partial-foggy program operation on the selected memory cells may include a plurality of program loops. Each of the program loops may include steps S310 to S370.

At step S310, as a result of performing a verify operation in the previous program loop at step S370, a program inhibition voltage may be applied to bit lines respectively coupled to the selected memory cells, which have been completely programmed to have the threshold voltages corresponding to the intermediate program state P_{IS} and the erase state E_{IS}. The threshold voltages of the program-completed memory cells of the intermediate program state P_{IS} and the erase state E_{IS} may be prevented from further programming. Thus, the program inhibition voltage may be applied to the bit lines respectively coupled to the program-completed memory cells so as not to increase the threshold voltages of the program-completed memory cells even when a program voltage is applied to a selected word line at step S350.

At step S330, a program permission voltage may be applied to bit lines coupled to the selected memory cells, which are not yet programmed to have the threshold voltages corresponding to the intermediate program state P_{IS} and the erase state E_{IS} as the result of performing the verify operation in the previous program loop at step S370. In this manner, when the program voltage is applied to the selected word line at step S350, the threshold voltages of the program-incomplete memory cells may increase.

At step S350, a program voltage may be applied to a word line coupled to the selected memory cells. The threshold voltages of program-incomplete memory cells may increase whereas the threshold voltages of the program-inhibited memory cells may not. The program-incomplete memory cells may be the selected memory cells still having the threshold voltages lower than the intermediate verify voltage VRF_{IS}. The program-inhibited memory cells may be the selected memory cells already having the threshold voltages greater than the intermediate verify voltage VRF_{IS}. At the early stage of the partial-foggy program operation, all memory cells may have threshold voltages corresponding to the erase state E₀. Therefore, all memory cells to be programmed to have the threshold voltages corresponding to the intermediate program state P_{IS} may be program-incomplete memory cells. As a program loop is repeated, the threshold voltages of the program-incomplete memory cells may gradually increase and the threshold voltages of some of the selected memory cells may become greater than the intermediate verify voltage VRF_{IS}. The selected memory cells, the threshold voltages of which become greater than the intermediate verify voltage VRF_{IS}, may become the program-inhibited cells. When the program loop continues to be repeated, the threshold voltages of the selected memory cells may eventually become greater than the intermediate verify voltage VRF_{IS}. As a result, all selected memory cells may be programmed to the intermediate program state P_{IS} and thus may be the program-inhibited cells.

The selected memory cells having the threshold voltages corresponding to the erase state E_{IS} may become the program-inhibited cells from the early stage of the partial-foggy program operation.

At step S370, a verify operation may be performed on the selected memory cells, through the intermediate verify voltage VRF_{IS}. The intermediate verify voltage VRF_{IS} may be applied to the selected word line. It may be determined whether the threshold voltages of the selected memory cells are greater than the intermediate verify voltage VRF_{IS}. The selected memory cells having threshold voltages greater than the intermediate verify voltage VRF_{IS} as a result of step S370 may become the program-inhibited cells.

Step S100 may end when the threshold voltages of all selected memory cells are determined to be greater than the intermediate verify voltage VRF_{IS} at step S390. When the threshold voltages of at least some of the selected memory cells are determined to be lower than the intermediate verify voltage VRF_{IS} at step S390, the process may proceed to step S310 and a subsequent program loop may be repeated.

As the partial-foggy program operation is performed as described above, a threshold voltage distribution corresponding to the initial erase state E₀ may be changed to correspond to the erase state E_{IS} and the intermediate program state P_{IS}. The memory cells of the erase state E_{IS} and the intermediate program state P_{IS} may be differentiated from each other according to the LSB of each memory cell. The threshold voltage distribution of the memory cells after the completion of the partial-foggy program operation may be divided into the erase state E_{IS} and the intermediate program state P_{IS}. Therefore, the LSB of each memory cell may be read using an intermediate read voltage R_{IS}.

Step S200 of performing the fine program operation on the selected memory cells using the first to seventh verify voltages may include step S315 of applying a program inhibition voltage to bit lines coupled to the selected memory cells programmed to have the threshold voltages corresponding to the target program states P1 to P7; step S335 of applying a program permission voltage to bit lines coupled to the selected memory cells not yet programmed to have the threshold voltages corresponding to the target program states P1 to P7; step S355 of applying a program voltage to a word line coupled to the selected memory cells; step S375 of performing a verify operation on the selected memory cells using first to seventh verify voltages VRF1 to VRF7; and step S395 of determining whether the selected memory cells are completely programmed to belong to the target program states P1 to P7.

Steps S315 to S375 may be repeated until the selected memory cells are programmed to have the threshold voltages corresponding to the target program states P1 to P7. The fine program operation of the selected memory cells may include a plurality of program loops. Each of the program loops may include steps S315 to S375.

At step S315, as a result of performing a verify operation in the previous program loop at step S375, a program inhibition voltage may be applied to bit lines respectively coupled to the selected memory cells, which have been completely programmed to have the threshold voltages corresponding to the target program states P1 to P7 and the erase state E. The threshold voltages of the program-completed memory cells of the target program states P1 to P7 and the erase state E may be prevented from further programming. Thus, the program inhibition voltage may be applied to the bit lines respectively coupled to the program-completed memory cells so as not to increase the threshold voltages of the program-completed memory cells even when a program voltage is applied to a selected word line at step S355.

At step S335, a program permission voltage may be applied to bit lines coupled to the selected memory cells, which are not yet programmed to have the threshold voltages corresponding to the target program states P1 to P7 and the erase state E as the result of performing the verify operation in the previous program loop at step S375. In this manner, when the program voltage is applied to the selected word line at step S355, the threshold voltages of the program-incomplete memory cells may increase.

At step S355, a program voltage may be applied to a word line coupled to the selected memory cells. The threshold voltages of program-incomplete memory cells may increase whereas the threshold voltages of the program-inhibited memory cells may not. The program-incomplete memory cells may be the selected memory cells still having the threshold voltages lower than the corresponding first to seventh verify voltages VRF1 to VRF7. The program-inhibited memory cells may be the selected memory cells already having the threshold voltages greater than the corresponding first to seventh verify voltages VRF1 to VRF7. At the early stage of the fine program operation, all memory cells may have threshold voltages corresponding to the erase state E_{IS} and the intermediate program state P_{IS}. Therefore, all memory cells to be programmed to have the threshold voltages corresponding to the respective target program states P1 to P7 may be program-incomplete memory cells. As a program loop is repeated, the threshold voltages of the program-incomplete memory cells may gradually increase and the threshold voltages of some of the selected memory cells may become greater than the corresponding first to seventh verify voltages VRF1 to VRF7. The selected memory cells, the threshold voltages of which become greater than the corresponding first to seventh verify voltages VRF1 to VRF7, may become the program-inhibited cells. When the program loop continues to be repeated, the threshold voltages of the selected memory cells may eventually become greater than the corresponding first to seventh verify voltages VRF1 to VRF7. As a result, all selected memory cells may be programmed to have the threshold voltages corresponding to the respective target program states P1 to P7 and thus may be the program-inhibited cells.

The selected memory cells having the threshold voltages corresponding to the erase state E may become the program-inhibited cells from the early stage of the partial-foggy program operation.

At step S375, a verify operation may be performed on the selected memory cells, through the corresponding first to seventh verify voltages VRF1 to VRF7. The first to seventh verify voltages VRF1 to VRF7 may be applied to the selected word line. It may be determined whether the threshold voltages of the selected memory cells are greater than the corresponding first to seventh verify voltages VRF1 to VRF7. The selected memory cells having threshold voltages greater than the corresponding first to seventh verify voltages VRF1 to VRF7 as a result of step S375 may become the program-inhibited cells.

Step S200 may end when the threshold voltages of all selected memory cells are determined to be greater than the corresponding first to seventh verify voltages VRF1 to VRF7 at step S395. When the threshold voltages of at least some of the selected memory cells are determined to be lower than the corresponding first to seventh verify voltages VRF1 to VRF7 at step S395, the process may proceed to step S315 and a subsequent program loop may be repeated.

As the fine program operation is performed as described above, the threshold voltage distribution corresponding to the erase state E_{IS} and the intermediate program state P_{IS} may be changed to correspond to the erase state E and the first to seventh target program states P1 to P7. The threshold voltages of the memory cells corresponding to the erase state E_{IS} may be changed to correspond to the erase state E and the first to third target program states P1 to P3. The threshold voltages of the memory cells corresponding to the intermediate program state P_{IS} may be changed to correspond to the fourth to seventh target program states P4 to P7.

The memory cells belonging to the erase state E and the first to seventh target program states P1 to P7 may be divided according to the values of MSB, CSB and LSB data. For example, the memory cell having the threshold voltage corresponding to the erase state E may have the MSB data of the value ‘0’, the CSB data of the value ‘1’, and the LSB data of the value ‘1’. For example, the memory cell having the threshold voltage corresponding to the first target program state P1 may have the MSB data of the value ‘0’, the CSB data of the value ‘0’, and the LSB of the value ‘1’.

For example, after completion of the partial-foggy-fine program operation, the LSB data programmed in each of the selected memory cells may be read through a predetermined read voltage. All memory cells having lower threshold voltages than the predetermined read voltage may have the LSB data of the value ‘1’ and all memory cells having higher threshold voltages than the predetermined read voltage may have the LSB data of the value ‘0’. Therefore, an LSB read operation may be performed on the memory cells through the predetermined read voltage. The read voltage for the LSB read operation after the partial-foggy program operation may be an intermediate read voltage R_{IS} and the read voltage for the LSB read operation after the fine program operation may be the predetermined read voltage greater than the intermediate read voltage R_{IS}.

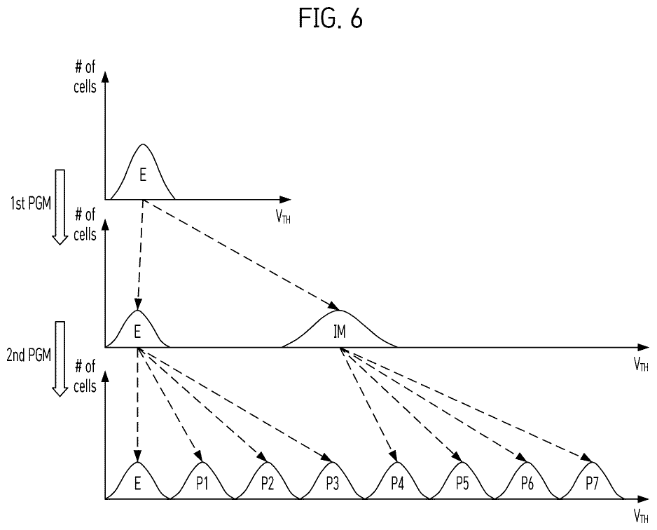

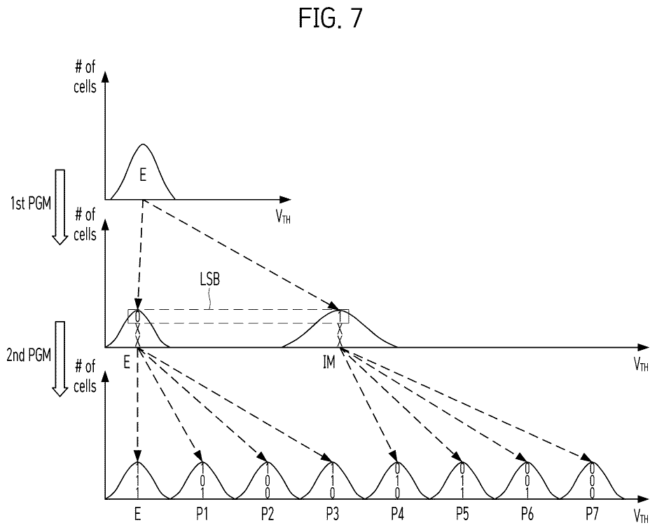

FIGS. 6 and 7 illustrate the partial-foggy-fine program operation on TLCs.

In the case of the partial-foggy-fine program operation of FIGS. 6 and 7, the storage device 130 may perform the partial-foggy program operation 1st PGM with the LSB page data. The LSB page data of values ‘0’ and ‘1’ may be distinguished according to a single read voltage.

Referring to FIGS. 6 and 7, the LSB page data of the memory cells having the threshold voltages corresponding to the erase state E and the first to third program states P1 to P3 may be the value ‘1’ and the LSB page data of the memory cells having the threshold voltages corresponding to the fourth to seventh program state P4 to P7 may be the value ‘0’.

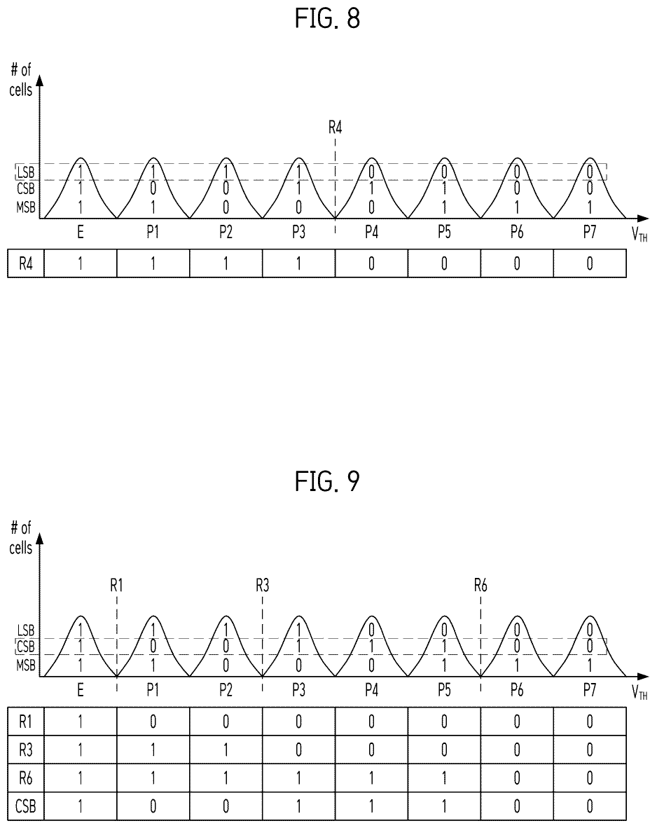

FIGS. 8 to 10 illustrate read operations on LSB, CSB and MSB pages of TLCs.

Referring to FIG. 8, during the read operation on the LSB page of TLCs, the LSB page data may be obtained through a single read voltage. For example, the LSB page data may be obtained through the fourth read voltage R4. The LSB data of the memory cell determined as the on-cell by the fourth read voltage R4 may be the value ‘1’. The LSB data of the memory cells determined as the off-cell by the fourth read voltage R4 may be the value ‘0’.

Referring to FIG. 9, during the read operation on the CSB page of TLCs, the CSB page data may be obtained through three different read voltages. For example, the CSB page data may be obtained through the first, third and sixth read voltages R1, R3 and R6. The CSB data of the memory cell determined as the on-cell by the first read voltage R1 may be the value ‘1’. The CSB data of the memory cells determined as the off-cell by the read voltage R1 and determined as the on-cell by the third read voltage R3 may be the value ‘0’. The CSB data of the memory cells determined as the off-cell by the third read voltage R3 and determined as the on-cell by the sixth read voltage R6 may be the value ‘1’. The CSB data of the memory cells determined as the off-cell by the sixth read voltage R6 may be the value ‘0’.

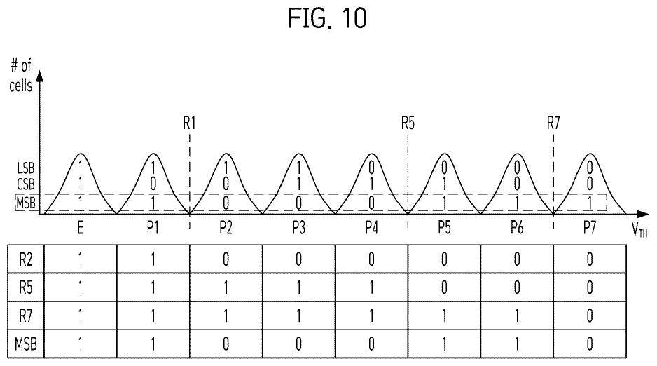

Referring to FIG. 10, during the read operation on the MSB page of TLCs, the MSB page data may be obtained through three different read voltages. For example, the MSB page data may be obtained through the second, fifth and seventh read voltages R2, R5 and R7. The MSB data of the memory cell determined as the on-cell by the second read voltage R2 may be the value ‘1’. The MSB data of the memory cells determined as the off-cell by the second read voltage R2 and determined as the on-cell by the fifth read voltage R5 may be the value ‘0’. The MSB data of the memory cell determined as the off-cell by the fifth read voltage R5 and determined as the on-cell by the seventh read voltage R7 may be the value ‘1’. The CSB data of the memory cells determined as the off-cell by the seventh read voltage R7 may be the value ‘0’.

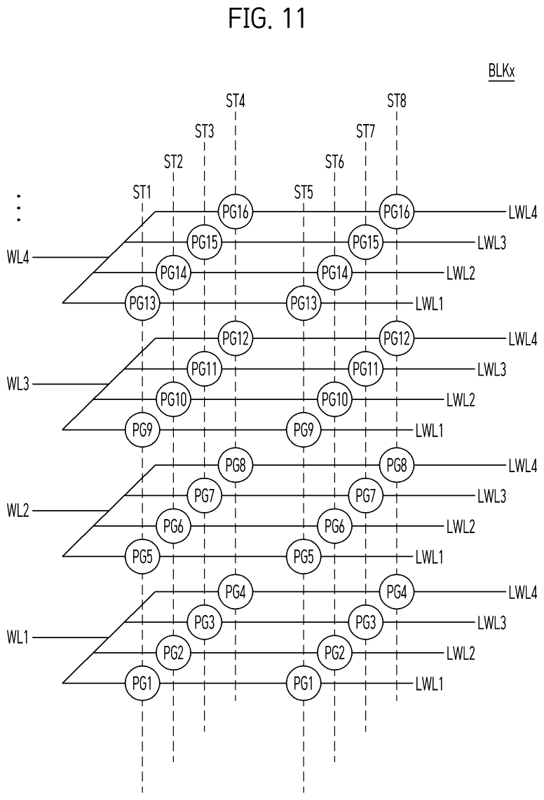

FIG. 11 schematically illustrates pages included in a memory block BLKx.

Referring to FIG. 11, the memory block BLKx may be connected to a plurality of physical word lines. One physical word line may be commonly connected to four logical word lines. Memory cells connected to any of the logical word lines may configure one page. For example, each of first to fourth physical word lines WL1 to WL4 may be commonly connected to first to fourth logical word lines LWL1 to LWL4.

For example, first to fourth strings ST1 to ST4 may be commonly connected to a bit line and fifth to eighth strings ST5 to ST8 may be commonly connected to another bit line.

For example, the number of logical word lines connected to one physical word line may be determined according to the number of strings commonly connected to one bit line. For example, when five strings are commonly connected to one bit line, one physical word line may be commonly connected to five local word lines. In this case, one physical word line may include five pages. Among the five pages, a programmed string and a not-yet-programmed string may be determined according to a string select signal (e.g., signals applied to the drain select line or the source select line).

The first logical word line LWL1 may be selected by the first string ST1 and the fifth string ST5. The second logical word line LWL2 may be selected by the second string ST2 and the sixth string ST6. The third logical word line LWL3 may be selected by the third string ST3 and the seventh string ST7. The fourth logical word line LWL4 may be selected by the fourth string ST4 and the eighth string ST8. One page may be selected by one logical word line and one physical word line.

That is, the first physical word line WL1 may include first to fourth pages PG1 to PG4. The second physical word line WL2 may include fifth to eighth pages PG5 to PG8. The third physical word line WL3 may include ninth to twelfth pages PG9 to PG12. The fourth physical word line WL4 may include thirteenth to sixteenth pages PG13 to PG16.

As discussed above, a partial-foggy program operation may be the foggy program operation of forming the threshold voltage distribution corresponding to a part of all program states supposed to be formed. A partial-foggy-fine program operation may include the partial-foggy program operation and a fine program operation. Unlike the partial-foggy program operation, an all-foggy program operation may be a foggy program operation of forming the threshold voltage distribution corresponding to all program states supposed to be formed. Unlike the partial-foggy-fine program operation, an all-foggy-fine program operation may include the all-foggy program operation and a fine program operation.

A storage device configured to perform a partial-foggy-fine program operation on QLC NAND memory cells has a 6-12% cost benefit for a storage system including the storage device over a storage device configured to perform an all-foggy-fine program operation on the QLC NAND memory cells because, during the partial-foggy-fine program operation, the storage device does not need any buffer unit, which is required to temporarily buffer write data during the all-foggy-fine program operation. During the partial-foggy-fine program operation, the storage device can directly program the write data into the memory cells without intervention of the buffer unit.

The QLC may be configured to store therein the least significant bit (LSB), lower-central significant bit (LCSB), upper-central significant bit (UCSB) and most significant bit (MSB), respectively. A LSB row among the QLCs connected to a word line may form the LSB page configured to store therein the LSBs. In a similar manner, a MSB row among the QLCs connected to the word line may form the MSB page configured to store therein the MSBs; a LCSB row among the QLCs connected to the word line may form the LCSB page configured to store therein the LCSBs; and a UCSB row among the QLCs connected to the word line may form the UCSB page configured to store therein the UCSBs. The QLCs may store 4-page data or the LSB, LCSB, UCSB and MSB page data.

According to the all-foggy-fine program operation, the 4-page data or the LSB, LCSB, UCSB and MSB page data needs to be programmed to the QLC twice at different points in time. The all-foggy program operation is performed at the first point in time when a host system provides a storage system with the 4-page data. At the first point in time, the storage device needs to buffer the same 4-page data for the subsequent fine program operation to be performed at the second point in time because the result of the all-foggy program operation on the QLC is not readable. The buffer unit may be either a SLC or a volatile memory.

According to the partial-foggy-fine program operation, the host system first provides the storage system with the 2 lower logical page data units, i.e., the LSB and LCSB page data, for the partial-foggy program operation and then with the 2 higher logical page data units, i.e., the UCSB and MSB data, for the fine program operation, during which the already-programmed 2 lower logical page data units (the LSB and LCSB page data) are internally read from the QLCs to the buffer units to have combined 4 logical page data units, i.e., the LSB, LCSB, UCSB and MSB page data.

According to the partial-foggy-fine program operation, which is different from the all-foggy-fine program operation, the 2 lower logical page data units (i.e., the LSB and LCSB page data) are programmed directly from the host system to the QLCs without buffering any data during the partial-foggy program operation. Unlike the all-foggy-fine program operation, the 2 lower page data units are readable as the result of the partial-foggy program operation. Thereafter, the storage device internally reads the already-programmed 2 lower logical page data units (the LSB and LCSB page data), i.e., the result of the partial-foggy program operation, combines the read 2 lower page data units with the 2 higher page data units (the UCSB and MSB page data), which are provided from the host system, and performs the fine program operation on the QLC with the combined 4-page data.

Although the embodiments of the present disclosure are disclosed with reference to an example of the QLC, the embodiments are not limited thereto. The embodiments may be applied to any type of partial-foggy program scheme having the feature of the internal pre-read operation.

One of the features of the partial-foggy-fine program operation may be an internal pre-read operation after the partial-foggy program operation.

During the partial-foggy program operation on the physical QLC page, 2 logical page data units or the LSB and LCSB page data may be programmed into the physical QLC page without buffering the LSB and LCSB page data.

After completion of the partial-foggy program operation, the storage device may perform the internal pre-read operation of internally reading the LSB and LCSB page data from the physical QLC page.

During the fine program operation on the physical QLC page, the storage device may combine the LSB and LCSB page data with the UCSB and MSB page data to program the combined 4 logical page data units into the physical QLC page. Here, the LSB and LCSB page data have been programmed into the physical QLC page during the partial-foggy program operation and have been internally read from the physical QLC page through the internal pre-read operation, and the UCSB and MSB page data are provided from the host system during the fine program operation.

In general, the partial-foggy-fine program operation may take longer time than the all-foggy-fine program operation and the partial-foggy-fine program operation may cause the less read window budget (RWB) margin than the all-foggy-fine program operation. The RWB margin is the sum of valley margins between adjacent distributions. A better/lower state width translates to a higher RWB margin.

As a known art, a pre-erase-tightening operation for the partial-foggy program operation can be utilized to bridge the reliability gap between the partial-foggy-fine program operation and all-foggy-fine program operation. The pre-erase-tightening operation can contribute toward a total of 2% of the amount of program time. Further, the internal pre-read operation for the fine program operation can contribute toward a total of 1% of the amount of program time.

With the artificial intelligence, cloud computing, big-data, and other highly data intensive applications of the storage devices, performance is one of the key factors to have an edge over the competition.

An embodiment of the present disclosure may provide a scheme of performing the pre-erase-tightening operation while receiving from an external the LCSB page data during the partial-foggy-fine program operation and performing the internal pre-read operation while receiving from the external the MSB page data during the fine program operation. According to an embodiment of the present disclosure, the amount of program time may be improved (i.e., reduced) by 1-3%.

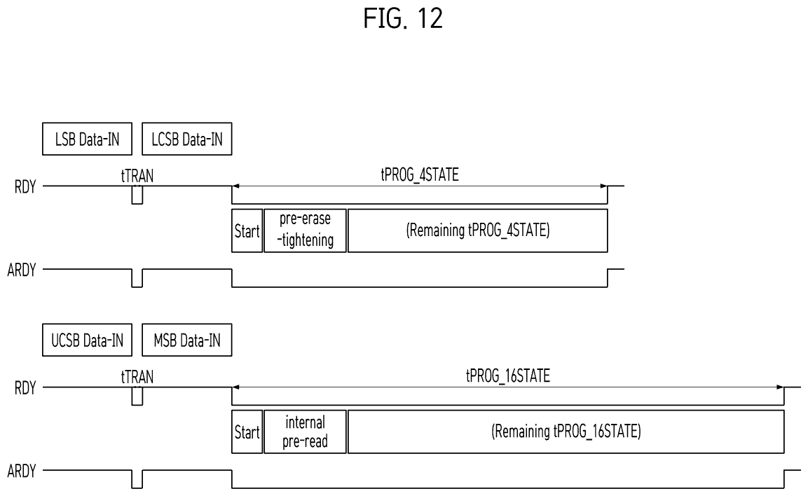

FIG. 12 is a timing diagram illustrating the partial-foggy-fine program operation.

During the partial-foggy program operation on the physical QLC page, the 2 lower logical page data units or the LSB and LCSB page data are programmed into the physical QLC page without buffering the LSB and LCSB page data.

Referring to FIG. 12, during the partial-foggy program operation, the storage device receives from the host system the LSB page data while both the RDY signal and ARDY signal stay ready. The RDY signal may be a ready/busy signal for the host system and the ARDY signal may be a ready/busy signal for the storage device.

Then, during the partial-foggy program operation, the storage device buffers the LSB page data while both the RDY signal and ARDY signal stay busy, which is marked as “tTRAN” in FIG. 12.

Then, during the partial-foggy program operation, the storage device receives from the host system the LCSB page data while both the RDY signal and ARDY signal stay ready.

Then, during the partial-foggy program operation, the storage device sequentially performs a start operation, the pre-erase-tightening operation and the program operation of storing both the LSB and LCSB page data while both the RDY signal and ARDY signal stay busy, which is marked as “tPROG_4STATE” in FIG. 12. The start operation includes an analog pump-warm-up operation, an address decoding operation and other logical computations required for initiating the program operation of storing the LSB and LCSB page data.

Upon completion of the program operation of storing the LSB and LCSB page data, both the RDY and ARDY signals become ready.

As described above, the storage device performs the pre-erase-tightening operation after completion of receiving the LCSB page data.

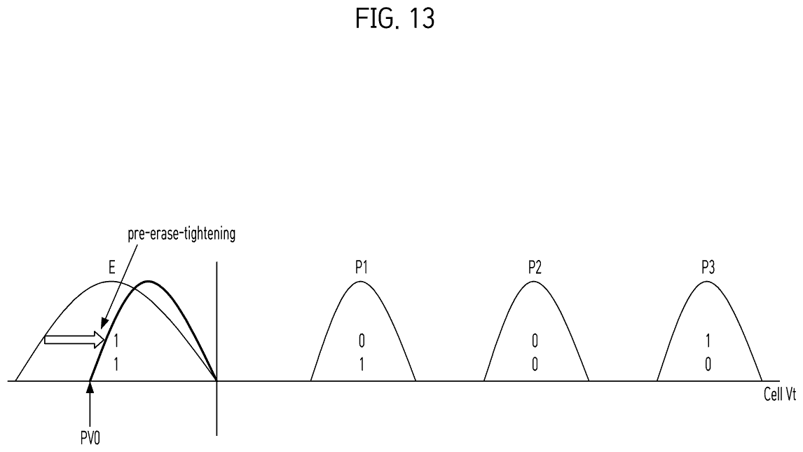

FIG. 13 illustrates the threshold voltage distribution as a result of the pre-erase-tightening operation within the partial-foggy program operation. FIG. 13 shows the tightened threshold voltage distribution corresponding to the erase state E as well as the threshold voltage distribution corresponding to the first to third program states P1 to P3 as the result of the partial-foggy program operation including the pre-erase-tightening operation.

The pre-erase-tightening operation is an operation of tightening the threshold voltage distribution corresponding to the erase state E by programming a target memory cell, which is supposed to have a threshold voltage corresponding to the erase state E, to have the higher threshold voltage than a pre-erase-pass threshold voltage PV0.

According to an embodiment of the present disclosure, the pre-erase-pass threshold voltage PV0 may correspond to a tightened threshold voltage distribution of the erase state and may be higher than a pass threshold voltage corresponding to an original or untightened threshold voltage distribution of the erase state.

The pre-erase-tightening operation starts with a pre-erase verification process of verifying whether target memory cells, which are supposed to have a threshold voltage corresponding to the erase state E, already have higher threshold voltages than the pre-erase-pass threshold voltage PV0. As a result of the pre-erase verification process on the target memory cells, a pre-erase-pass memory cell verified as having a higher threshold voltage than the pre-erase-pass threshold voltage PV0 becomes program-inhibited during subsequent program loops each including a program pulse application process and a verification process.

After the pre-erase verification process during the pre-erase-tightening operation within the partial-foggy program operation, the storage device performs a program pulse application process of applying a program pulse to all target memory cells except the pre-erase-pass memory cell, which has been program-inhibited, and then the storage device performs the verification process according to the pre-erase-pass threshold voltage PV0 such that more memory cells become the pre-erase-pass memory cells.

After completion of the pre-erase-tightening operation within the partial-foggy program operation, the storage device performs program loops for the first to third program states P1 to P3 for the target memory cells to become to have higher threshold voltages than the pass threshold voltages corresponding to the respectively first to third program states P1 to P3.

While the program loops progress during the partial-foggy program operation, the majority of the target memory cells, which are supposed to have the threshold voltages corresponding to the erase state E, become the pre-erase-pass memory cells.

Upon completion of the partial-foggy program operation of storing the LSB and LCSB page data, both the RDY and ARDY signals become ready.

As described above, the storage device performs the pre-erase-tightening operation after completion of receiving the LCSB page data.

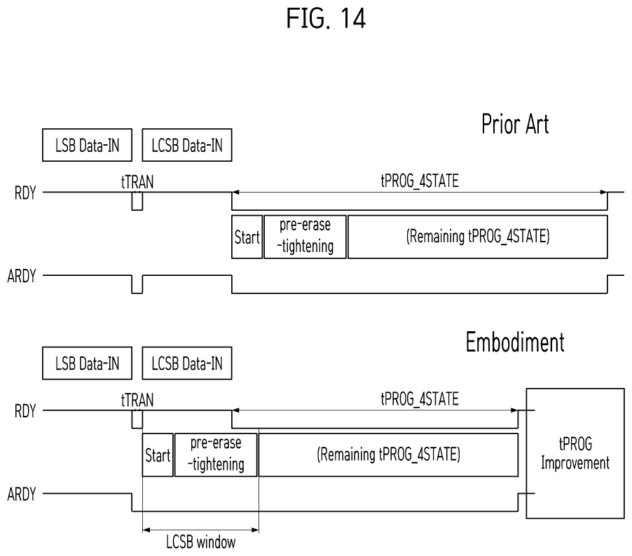

FIG. 14 is a timing diagram illustrating the partial-foggy program operations according to the prior art and an embodiment of the present disclosure. FIG. 14 shows again, for comparison purposes, the partial-foggy program operation according to the prior art as shown in FIG. 13.

Referring to FIG. 14, during the partial-foggy program operation according to an embodiment of the present disclosure, the storage device 130 may receive from the host system 200 the LSB page data while both the RDY signal and ARDY signal stay ready.

Then, during the partial-foggy program operation according to an embodiment of the present disclosure, the storage device 130 may buffer the LSB page data while both the RDY signal and ARDY signal stay busy, which is marked as “tTRAN” in FIG. 14.

Then, during the partial-foggy program operation according to an embodiment of the present disclosure, the storage device 130 may receive from the host system 200 the LCSB page data while the RDY signal stays ready and the ARDY signal keeps staying busy.

While receiving the LCSB page data with the RDY signal staying ready and the ARDY signal staying busy, the storage device 130 may sequentially perform the start operation and the pre-erase-Tightening operation.

The pre-erase-tightening operation may start with the pre-erase verification process of verifying whether target memory cells, which are supposed to have a threshold voltage corresponding to the erase state E, already have higher threshold voltages than the pre-erase-pass threshold voltage PV0. As a result of the pre-erase verification process on the target memory cells, the pre-erase-pass memory cell verified as having a higher threshold voltage than the pre-erase-pass threshold voltage PV0 may become program-inhibited during subsequent program loops each including a program pulse application process and a verification process.

According to an embodiment of the present disclosure, after the pre-erase verification process during the pre-erase-tightening operation within the partial-foggy program operation, the storage device 130 may perform a pre-program loop including a program pulse application process and a verification process. During the pre-program loop, the storage device 130 may perform the program pulse application process of applying a program pulse to all target memory cells except the pre-erase-pass memory cell, which has been program-inhibited, and then the storage device 130 may perform the verification process according to the pre-erase-pass threshold voltage PV0 such that more target memory cells become the pre-erase-pass memory cells.

According to an embodiment of the present disclosure, after completion of the pre-erase-tightening operation within the partial-foggy program operation, the RDY signal may stay busy and the ARDY signal keeps staying busy and the storage device 130 may perform program loops for the first to third program states P1 to P3 for the target memory cells to become to have higher threshold voltages than the pass threshold voltages corresponding to the respective first to third program states P1 to P3.

As described above, according to an embodiment of the present disclosure, the storage device 130 may be performing the pre-erase-tightening operation while receiving the LCSB page data, which means that the LCSB page data may not be available for the storage device 130 during the pre-erase-tightening operation in progress and therefore the storage device 130 may not clearly identify the target memory cell, which is supposed to have the threshold voltage corresponding to the erase state E, during the pre-erase-tightening operation in progress. In general, a target memory cell supposed to have the threshold voltage corresponding to the erase state E may be clearly identified according to both the LSB and LCSB page data.

According to an embodiment of the present disclosure, the storage device 130 may perform the pre-erase verification process on all target memory cells during the pre-erase-tightening operation. According to an embodiment of the present disclosure, the pre-erase-tightening operation may further include a cell-status-change operation as well as the pre-erase verification process and pre-program loop.

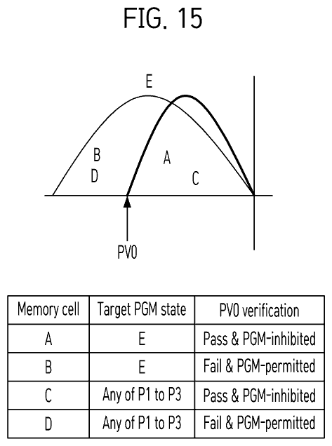

As a result of the pre-erase verification process according to an embodiment of the present disclosure, there could be four different groups A to D for all target memory cells as shown in FIG. 15.

FIG. 15 schematically illustrates target memory cells as a result of the pre-erase verification process according to an embodiment of the present disclosure.

Referring to FIG. 15, first and second groups A and B of target memory cells may be supposed to have threshold voltages corresponding to the erase state E. As a result of the pre-erase verification process, the first group A may be verified as having higher threshold voltages than the pre-erase-pass threshold voltage PV0 and therefore may become program-inhibited. As a result of the pre-erase verification process, the second group B may be verified as having lower threshold voltages than the pre-erase-pass threshold voltage PV0 and therefore may stay program-permitted.

The target memory cells of the second group B may become the pre-erase-pass memory cells as the subsequent program loops progress after the pre-erase-tightening operation.

Referring to FIG. 15, third and fourth groups C and D of target memory cells may be supposed to have threshold voltages corresponding to any of first to third program states P1 to P3 other than the erase state E. As a result of the pre-erase verification process, the third group C may be verified as having higher threshold voltages than the pre-erase-pass threshold voltage PV0 and therefore may become program-inhibited. As a result of the pre-erase verification process, the fourth group D may be verified as having lower threshold voltages than the pre-erase-pass threshold voltage PV0 and therefore may stay program-permitted.

The target memory cells of the fourth group D may become to have threshold voltages corresponding to a respective target program state among the first to third program states P1 to P3 as the subsequent program loops progress after the pre-erase-tightening operation.

As discussed above, the target memory cells of the third group C may become program-inhibited as the result of the pre-erase-tightening operation although the target memory cells of the third group C are supposed to have threshold voltages corresponding to the respective first to third program states P1 to P3 other than the erase state E. Therefore, the target memory cells of the third group C need to become program-permitted so that the program pulses are applied to the target memory cells of the third group C to become to have threshold voltages corresponding to a respective target program state among the first to third program states P1 to P3 as the subsequent program loops progress after the pre-erase-tightening operation.

According to an embodiment of the present disclosure, the storage device 130 may perform, after completion of the program pulse application process within the pre-program loop of the pre-erase-tightening operation, the cell-status-change operation of changing the status of the target memory cells of the third group C such that the target memory cells of the third group C become program-permitted.

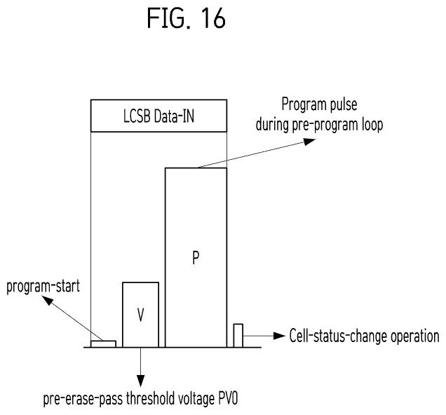

FIG. 16 illustrates the relationship among the pre-erase verification process, the program pulse application process and the cell-status-change operation within the pre-erase-tightening operation according to an embodiment of the present disclosure.

Referring to FIG. 16, during the pre-erase-tightening operation according to an embodiment of the present disclosure, the storage device 130 may be performing the pre-erase-tightening operation while receiving the LCSB page data from the host system.

During the pre-erase-tightening operation, the storage device 130 may perform the pre-erase verification process on all target memory cells and then may perform the program pulse application process of the pre-program loop.

After completion of the program pulse application process within the pre-program loop of the pre-erase-tightening operation, the storage device 130 may perform the cell-status-change operation of changing the status of the target memory cells of the third group C such that the target memory cells of the third group C become program-permitted. As described above, the target memory cells of the third group C may be memory cells, which are supposed to have threshold voltages corresponding to the respective first to third program states P1 to P3 other than the erase state E.

During the cell-status-change operation, the storage device 130 may determine whether the LCSB page data is received and thus the LCSB page data becomes available.

When the LCSB page data is determined to be available, the storage device 130 may utilize the LSB and LCSB page data to identify the target memory cells of the group C or the target memory cells, which are supposed to have threshold voltages corresponding to the respective first to third program states P1 to P3 other than the erase state E, and to change the status of the target memory cells such that the target memory cells become program-permitted. The storage device 130 may perform a logical AND operation on the LSB and LCSB page data to identify the memory cells belonging to the erase state E, which are represented by the LSB and LCSB page data each of a value one (1) in an example of FIG. 13. Remaining memory cells other than the memory cells belonging to the erase state E may be the target memory cells of the group C or the target memory cells, which are supposed to have threshold voltages corresponding to the respective first to third program states P1 to P3 other than the erase state E. Then, the storage device 130 may perform the subsequent program loops to program the target memory cells of the third group C to have threshold voltages corresponding to the respective first to third program states P1 to P3.

As described above, according to an embodiment of the present disclosure, the storage device 130 may perform, even without the LCSB page data, the pre-erase verification process and the program pulse application process of the pre-program loop within the pre-erase-tightening operation. According to an embodiment of the present disclosure, the storage device 130 may perform the cell-status-change operation further included in the pre-erase-tightening operation to identify the target memory cells, which are supposed to have threshold voltages corresponding to the respective first to third program states P1 to P3 other than the erase state E, and to change, as program-permitted, the status of the target memory cells such that the target memory cells, which have been program-inhibited by the pre-erase verification process, become program-permitted. Then, the storage device 130 may perform the subsequent program loops to program the program-permitted target memory cells to have threshold voltages corresponding to the respective first to third program states P1 to P3.

As discussed above, the target memory cells, which are supposed to have threshold voltages corresponding to the respective first to third program states P1 to P3 other than the erase state E, have been program-inhibited by the pre-erase verification process, and therefore, the storage device 130 may not apply the program pulse to the target memory cells, which are supposed to have threshold voltages corresponding to the respective first to third program states P1 to P3 other than the erase state E, during the program pulse application process within the pre-program loop. The program-inhibition of the target memory cells, which are supposed to have threshold voltages corresponding to the respective first to third program states P1 to P3 other than the erase state E, during the program pulse application process within the pre-program loop may be an ignorable issue because (1) the target memory cells, which are supposed to have threshold voltages corresponding to the respective first to third program states P1 to P3 other than the erase state E, are targeted for higher threshold voltages corresponding to respective first to third program states P1 to P3; (2) the target memory cells, which are supposed to have threshold voltages corresponding to the respective first to third program states P1 to P3 other than the erase state E, already have higher threshold voltages than the target memory cells of the group D or the target memory cells, which are supposed to have threshold voltages corresponding to the respective first to third program states P1 to P3 other than the erase state E but have failed the pre-erase verification process, to begin the subsequent program loops with; and (3) the program-pulse of the program pulse application process within the pre-program loop has a very small voltage level to avoid valley disturbance, which does not move, by a considerable amount, the threshold voltage distribution of the target memory cells, which are supposed to have threshold voltages corresponding to the respective first to third program states P1 to P3 other than the erase state E, even if the program pulse having very small voltage level is applied to the target memory cells, which are supposed to have threshold voltages corresponding to the respective first to third program states P1 to P3 other than the erase state E, during the program pulse application process within the pre-program loop of the pre-erase-tightening operation.

During the fine program operation after completion of the partial-foggy program operation according to an embodiment of the present disclosure, the storage device 130 may perform the internal pre-read operation of internally reading the LSB and LCSB page data from the physical QLC page.

Referring back to FIG. 12, during the fine program operation after the completion of the partial-foggy-fine program operation, the storage device receives from the host system the UCSB page data while both the RDY signal and ARDY signal stay ready.

Then, during the fine program operation, the storage device buffers the UCSB page data while both the RDY signal and ARDY signal stay busy, which is marked as “tTRAN” in FIG. 12.

Then, during the fine program operation, the storage device receives from the host system the MSB page data while both the RDY signal and ARDY signal stay ready.

Then, during the fine program operation, the storage device sequentially performs a start operation, the internal pre-read operation and the program operation of storing the combination of the 4 logical page data, or the combination of LSB, LCSB, UCSB and MSB page data while both the RDY signal and ARDY signal stay busy, which is marked as “tPROG_16STATE” in FIG. 12. The start operation includes analog pump-warm-up operation, address decoding operation and other logical computations required for initiating the program operation of storing the combination of LSB, LCSB, UCSB and MSB page data.

The internal pre-read operation is an operation of internally reading the LSB and LCSB page data from the physical QLC page. As a result of the reception of UCSB and MSB page data and the internal pre-read operation, the combination of LSB, LCSB, UCSB and MSB page data becomes available for the fine program operation.

After completion of the internal pre-read operation, the storage device combines the LSB and LCSB page data with the UCSB and MSB page data to program the combined 4 logical page data units into the physical QLC page. As described above, the LSB and LCSB page data have been programmed into the physical QLC page during the partial-foggy program operation and have been internally read from the physical QLC page through the internal pre-read operation, and the UCSB and MSB page data are provided from the host system during the fine program operation.

Upon completion of the program operation of storing the combination of LSB, LCSB, UCSB and MSB page data, both the RDY and ARDY signals become ready.

As described above, the storage device performs the internal pre-read operation after completion of receiving the MSB page data.

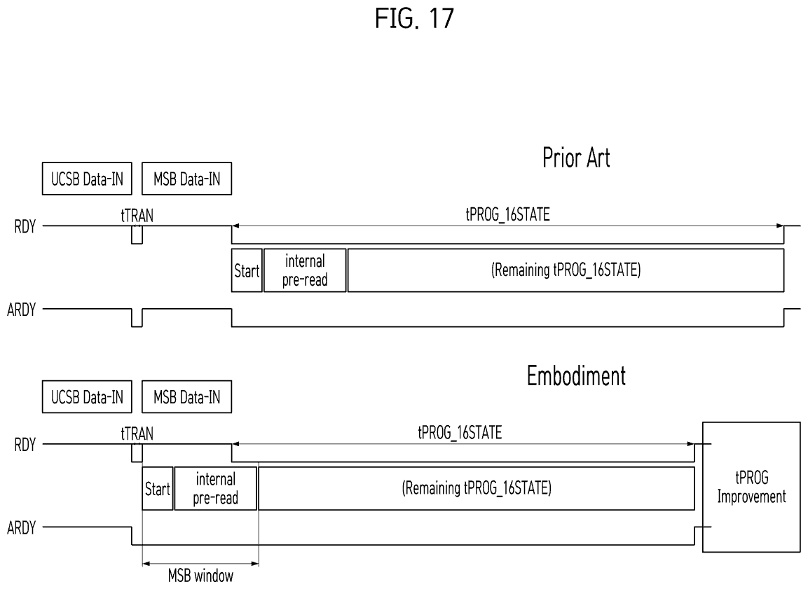

FIG. 17 is a timing diagram illustrating the fine program operations according to the prior art and an embodiment of the present disclosure. FIG. 17 shows again, for comparison purposes, the fine program operation according to the prior art as shown in FIG. 13.

Referring to FIG. 17, during the fine program operation after the partial-foggy program operation according to an embodiment of the present disclosure, the storage device 130 may receive from the host system 200 the UCSB page data while both the RDY signal and ARDY signal stay ready.

Then, during the fine program operation according to an embodiment of the present disclosure, the storage device 130 may buffer the UCSB page data while both the RDY signal and ARDY signal stay busy, which is marked as “tTRAN” in FIG. 17.

Then, during the fine program operation according to an embodiment of the present disclosure, the storage device 130 may receive from the host system 200 the MSB page data while the RDY signal stays ready and the ARDY signal keeps staying busy.

While receiving the MSB page data with the RDY signal staying ready and the ARDY signal staying busy, the storage device 130 may sequentially perform the start operation and the internal pre-read operation.

The internal pre-read operation is an operation of internally reading the LSB and LCSB page data from the physical QLC page. As a result of the reception of UCSB and MSB page data and the internal pre-read operation, the combination of LSB, LCSB, UCSB and MSB page data becomes available for the fine program operation.

After completion of the internal pre-read operation, the storage device 130 may combine the LSB and LCSB page data with the UCSB and MSB page data to program the combined 4 logical page data units into the physical QLC page.

According to an embodiment of the present disclosure, as the internal pre-read operation is performed while the MSB page data is provided from the host system 200, the host system 200 may experience a reduced amount of program time when compared with the prior art.

The reduction of the amount of program time depends on the IO speed of the storage device 130 and the number of planes within the storage device 130. The storage device 130 with a slower IO speed and/or the greater number of planes would experience more reduction in the amount of program time.

For example, the storage device 130 with 6 planes and 3.2 Gbps IO speed would take 35.5 us to receive the LCSB page data and would take another 35.5 us to receive the MSB page data, which is how much program time reduction the host system 200 would experience according to an embodiment of the present disclosure.

For example, the storage device 130 with 6 planes and 2.4 Gbps IO speed would take 44.5 us to receive the LCSB page data and would take another 44.5 us to receive the MSB page data, which is how much program time reduction the host system 200 would experience according to an embodiment of the present disclosure.

To get the most program time reduction, the host system 200 may provide the storage device 130 with the LCSB and MSB page data during the data windows “LCSB window” and “MSB window” respectively shown in FIGS. 14 and 17.

There could be exceptional cases (1) where the host system 200 may not be able to meet the requirements for the pre-erase-tightening operation and internal pre-read operation within the partial-foggy-fine program operation according to an embodiment of the present disclosure; and (2) where the host system 200 disables the pre-erase-tightening operation and/or internal pre-read operation.

When the host system 200 provides the storage device 130 with the LSB page data during the partial-foggy program operation according to an embodiment of the present disclosure, the storage device 130 may first check whether both the pre-erase-tightening operation and a concurrent IO feature are enabled. Only when both the pre-erase-tightening operation and concurrent IO feature are enabled, the storage device 130 may perform the partial-foggy program operation according to an embodiment of the present disclosure.

When the concurrent IO feature is enabled, the storage device 130 may sequentially perform the start operation and the pre-erase-tightening operation while receiving the LCSB page data with the RDY signal staying ready and the ARDY signal staying busy. After completion of the program pulse application process within the pre-program loop of the pre-erase-tightening operation, the storage device 130 may perform the cell-status-change operation of determining whether the LCSB page data is received and thus the LCSB page data becomes available and changing the status of the target memory cells, which are supposed to have threshold voltages corresponding to the respective first to third program states P1 to P3 other than the erase state E, such that the target memory cells become program-permitted.

When the LCSB page data is determined not yet available as a result of the cell-status-change operation, the storage device 130 may set a first flag to represent that the pre-erase-tightening operation is still in progress. Then, the storage device 130 may suspend the current partial-foggy-fine program operation and have both the RDY and ARDY signals become ready for another operation.

When the LCSB page data becomes available later, the storage device 130 may check whether the first flag is set. When the first flag is set, the storage device 130 may release the first flag to resume the suspended partial-foggy-fine program operation.

When the host system 200 provides the storage device 130 with the UCSB page data during the fine program operation after completion of the partial-foggy program operation according to an embodiment of the present disclosure, the storage device 130 may first check whether both the internal pre-read operation and the concurrent IO feature are enabled. Only when both the internal pre-read operation and concurrent IO feature are enabled, the storage device 130 may perform the fine program operation according to an embodiment of the present disclosure.

When the concurrent IO feature is enabled, the storage device 130 may sequentially perform the start operation and the internal pre-read operation while receiving the MSB page data with the RDY signal staying ready and the ARDY signal staying busy. After completion of the internal pre-read operation, the storage device 130 may determine whether the MSB page data is received and thus the MSB page data becomes available.

When the MSB page data is determined not yet available as a result of the determination, the storage device 130 may set a second flag to represent that the fine program operation is still in progress. Then, the storage device 130 may suspend the current fine program operation and have both the RDY and ARDY signals become ready for another operation.

When the LCSB page data becomes available later, the storage device 130 may check whether the second flag is set. When the second flag is set, the storage device 130 may release the second flag to resume the suspended fine program operation.

In summary, according to the embodiment of the present disclosure, the amount of program time may be reduced by 1-3%.

Although the foregoing embodiments have been illustrated and described in some detail for purposes of clarity and understanding, the present disclosure is not limited to the embodiments provided. There are many alternative ways of implementing the invention, as one skilled in the art will appreciate in light of the foregoing disclosure. The disclosed embodiments are thus illustrative, not restrictive. The present invention is intended to embrace all modifications and alternatives of the disclosed embodiments. Furthermore, the disclosed embodiments may be combined to form additional embodiments.

Indeed, implementations of the subject matter and the functional operations described in the present disclosure can be implemented in various systems, digital electronic circuitry, or in computer software, firmware, or hardware, including the structures disclosed in this specification and their structural equivalents, or in combinations of one or more of them. Embodiments of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter affecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and one or more processors of any type of digital computer. Generally, a processor will receive instructions and data from a read only memory or a random-access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices. The processor and the memory can be supplemented by, or incorporated in, special purpose logic circuitry.

While present disclosure contains many specifics, these should not be construed as limitations on the scope of any invention or of what may be claimed, but rather as descriptions of features that may be specific to particular embodiments of particular inventions. Certain features that are described in the present disclosure in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or a variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few embodiments and examples are described and other embodiments, enhancements and variations can be made based on what is described and illustrated in the present disclosure. Furthermore, the embodiments may be combined to form additional embodiments.

What is claimed is:

1. An operating method of a storage device, the method comprising:
performing a partial-foggy program operation of programming, into a physical page including target memory cells, lower logical page data units externally provided; and
performing a fine program operation of programming, into the physical page, a combination of higher logical page data units externally provided and the lower logical page data units read from the physical page,
wherein the performing the partial-foggy program operation includes:
performing a pre-erase-tightening operation on the target memory cells within the physical page while a last lower logical page data unit is being externally provided; and
performing subsequent program loops on the physical page with the lower logical page data units which are completely provided to the storage device.

2. The operating method of claim 1, wherein:
each of the target memory cells is a quadruple-level cell;
the lower logical page data units are least significant bit (LSB) page data and lower-central significant bit (LCSB) page data; and
the higher logical page data units are upper-central significant bit (UCSB) page data and most significant bit (MSB) page data.

3. The operating method of claim 2, wherein the partial-foggy program operation is performed for each of the target memory cells to belong to one of an erase state and first to third program states.

4. The operating method of claim 2, wherein the last lower logical page data unit is the LCSB page data.

5. The operating method of claim 2, wherein the subsequent program loops are performed according to an incremental step pulse program scheme.

6. The operating method of claim 2,
wherein the performing the pre-erase-tightening operation includes:
performing a pre-erase verification process of verifying the target memory cells with a pre-erase-pass threshold voltage to program-inhibit a pre-erase-pass memory cell having a higher threshold voltage than the pre-erase-pass threshold voltage among the target memory cells; and
performing a pre-program loop including a program pulse application process and a verification process on remaining target memory cells other than the pre-erase-pass memory cell among the target memory cells,
wherein the program pulse application process includes applying a program pulse to the remaining target memory cells, and
wherein the verification process includes verifying the remaining target memory cells with the pre-erase-pass threshold voltage to program-inhibit a target memory cell which becomes to have a higher threshold voltage than the pre-erase-pass threshold voltage among the remaining target memory cells.

7. The operating method of claim 6, wherein the pre-erase-pass threshold voltage is higher than a pass threshold voltage corresponding to an erase state.

8. The operating method of claim 7, wherein the performing the pre-erase-tightening operation further includes performing, after completion of the program pulse application process, a cell-status-change operation of changing the target memory cells which are to have threshold voltages corresponding to the respective program states other than an erase state and have been program-inhibited by the pre-erase-tightening operation, to become program-permitted.

9. The operating method of claim 8, wherein the cell-status-change operation is performed based on the lower logical page data units which are completely provided to the storage device.

10. The operating method of claim 9, wherein the performing the pre-erase-tightening operation further includes suspending the partial-foggy program operation when the lower logical data units are not yet completely provided to the storage device during the cell-status-change operation.

11. The operating method of claim 10, wherein the performing the pre-erase-tightening operation further includes resuming the suspended partial-foggy program operation when the lower logical data units are completely provided to the storage device.

12. The operating method of claim 1, wherein the performing the fine program operation includes:
performing an internal pre-read operation of internally reading the lower logical page data units from the physical page while a last higher logical page data unit is being externally provided;
combining the externally provided higher logical page data units which are completely provided to the storage device, and the lower logical page data units read from the physical page; and
performing subsequent program loops on the physical page with the combined data units.

13. The operating method of claim 12, wherein:
each of the target memory cells is a quadruple-level cell;
the lower logical page data units are least significant bit (LSB) page data and lower-central significant bit (LCSB) page data;
the higher logical page data units are upper-central significant bit (UCSB) page data and most significant bit (MSB) page data; and
the last lower logical page data unit is the MSB page data.

14. The operating method of claim 13, wherein the fine program operation is performed for each of the target memory cells to belong to one of an erase state and first to fifteenth program states.

15. The operating method of claim 12, wherein the performing the fine program operation further includes suspending the fine program operation when the higher logical data units are not yet completely provided to the storage device during the internal pre-read operation.

16. The operating method of claim 15, wherein the performing the fine program operation further includes resuming the suspended fine program operation when the higher logical data units are completely provided to the storage device.
